(19) United States
(12) Patent Application Publication
(10) Pub. No.: US 2024/0112943 A1
(43) Pub. Date: Apr. 4, 2024

(54) DIE SUCTION ASSISTANCE DEVICE

(71) Applicant: PANJIT INTERNATIONAL INC., Kaohsiung City (TW)

(72) Inventors: Chung-Hsiung HO, Kaohsiung City (TW); Chi-Hsueh LI, Tainan City (TW); Wen-Liang HUANG, Kaohsiung City (TW)

(73) Assignee: PANJIT INTERNATIONAL INC., Kaohsiung City (TW)

(21) Appl. No.: 17/983,305

(22) Filed: Nov. 8, 2022

(30) Foreign Application Priority Data
Sep. 29, 2022 (TW) 111137047

(51) Int. Cl. H01L 21/683

(52) U.S. Cl. CPC H01L 21/6836; H01L 21/6838; H01L 2221/68318; H01L 2221/68354; H01L 2221/68381

(57) ABSTRACT

A die suction assistance device is provided to a wafer. The wafer is diced into multiple dies, and a tape is taped on a bottom side of the wafer. The die suction assistance device includes a platform and multiple support structures mounted in the platform. Multiple air ducts are formed among adjacent support structures. When the wafer is air-tightly mounted on the platform, the wafer is supported by the support structures. When an external vacuum device vacuums air out of the platform, a vacuum environment with negative pressure is created in the air ducts. This allows the tape to partially separate from a backside of each of the dies towards the air ducts, and allows the dies to be picked up respectively by a suction nozzle with less chance of being damaged, securing integrities of dies.

### CROSS-REFERENCE TO RELATED APPLICATION(S)

This application claims the priority benefit of TW application serial No. 111137047 filed on Sep. 29, 2022, the entirety of which is hereby incorporated by reference herein and made a part of the specification.

### BACKGROUND OF THE INVENTION

### 1. Field of the Invention

The present invention relates to a die suction assistance device allowing diced dies of a wafer to be more easily picked up and with less damage to the dies.

### 2. Description of the Related Art

With reference to FIGS. 5A to 5C, flow charts of using a conventional die suction device are shown.

With reference to FIG. 5A, a wafer 100 is completely diced. A tape 200 is taped on a backside of the wafer 100, and a wafer frame 102 is configured to fix the wafer 100 and the tape 200 in place. Multiple individual dies 101 are formed as the wafer 100 is diced.

With reference to FIG. 5B, in order to individually pick up each of the dies 101, an expanding process is needed to be executed for expanding the tape 200 to increase spacing between adjacent dies 101.

With reference to FIG. 5C, an ejector 300 is mounted below the wafer 100, and at least one pushing pin 301 is stored within the ejector 300. When the ejector 300 ejects the at least one pushing pin 301, the ejected at least one pushing pin 301 pushes against one of the dies 101, causing the particular die 101 to slightly separate from the tape 200. A suction nozzle 400 right above the wafer 100 would then be able to suck in the particular die 101 that is pushed by the at least one pushing pin 301 away from the tape 200. As such, the particular die 101 is successfully picked up from the tape 200.

However, during the extraction of the particular die 101, as the tape 200 below the particular die 101 is expanded due to the push from the ejector 300, adjacent dies 101A surrounding the particular die 101 are pushed toward other dies 101B due to deformation of the tape 200. As a result, the adjacent dies 101A may collide with the other dies 101B and cause chips/cracks 501 to form on the adjacent dies 101A and the other dies 101B.

With further reference to FIGS. 6A and 6B, the chips/cracks 501 are formed on a few of the dies 101 due to, as described previously and as illustrated in FIG. 5C, collisions C that happen between the adjacent dies 101A and the other dies 101B when attempting to pick up the particular die 101 through die pushing by the ejector 300 and die sucking by the suction nozzle 400. As the at least one pushing pin 301 is quickly ejected towards the particular die 101, the at least one pushing pin 301 causes pin wounds 502 to form on a backside of the particular die 101, and possibly also causes residues of the tape 200 to remain on the backside of the particular die 101.

Furthermore, when the at least one pushing pin 301 pushes against the particular die 101, the particular die 101 might be pushed tilted, causing the suction nozzle 400 to suck on the particular die 101 unevenly, and possibly also causing the suction nozzle 400 to collide with the tilted particular die 101.

### SUMMARY OF THE INVENTION

To solve the aforementioned problem of possibly damaging dies when picking up the dies, the present invention provides a die suction assistance device. The die suction assistance device allows dies to be safely picked up, securing integrities of dies.

The die suction assistance device of the present invention is provided to a wafer. The wafer is diced into multiple dies, and a tape is taped on a bottom side of the wafer. The die suction assistance device of the present invention includes:
a platform, having an air cell; wherein at least one vacuum hole is formed in the platform; wherein the at least one vacuum hole is in fluid communication with the air cell, and the at least one vacuum hole is connected to an external vacuum device for vacuuming air out of the air cell;
multiple support structures, mounted in the platform; wherein multiple air ducts are formed among the support structures, and the multiple air ducts are in fluid communication with the air cell;
wherein the wafer is air-tightly mounted on the platform, and the support structures are configured to push against the tape;
wherein when the external vacuum device vacuums air out of the air cell, the tape and the dies are partially separated.

The present invention also provides another die suction assistance device. This die suction assistance device is provided to a wafer. The wafer is diced into multiple dies, and a tape is taped on a bottom side of the wafer. This die suction assistance device includes:
a platform, having an air cell; wherein at least one vacuum hole is formed in the platform; wherein the at least one vacuum hole is in fluid communication with the air cell, and the at least one vacuum hole is connected to an external vacuum device for vacuuming air out of the air cell;
a loading plate, mounted within the air cell of the platform; wherein multiple support structures are formed on the loading plate, multiple air ducts are formed among the support structures, and the multiple air ducts are in fluid communication with the air cell;
wherein the wafer is air-tightly mounted on the platform and the wafer is supported by the loading plate, and the support structures are configured to push against the tape;
wherein when the external vacuum device vacuums air out of the air cell, the tape and the dies are partially separated.

Both of the aforementioned die suction assistance devices of the present invention relies on the external vacuum device to vacuum air out of the air cell. As the external vacuum device creates a vacuum environment below the tape, the tape is able to unstick from each of the dies. The vacuum environment decreases an adhesive force between each of the dies and the tape, and allows all of the dies to be picked up by a suction nozzle in horizontal positions. This means that adjacent dies are able to avoid collisions, probability of forming chips or cracks in the dies are drastically lowered, and a backside of each of the dies is able to avoid having pin wounds.

### BRIEF DESCRIPTION OF THE DRAWINGS

FIG. 1 is a side perspective view of a diced wafer.

FIG. 2A is a perspective view of a die suction assistance device in a first embodiment of the present invention.

FIGS. 2B and 2C are perspective views of using the die suction assistance device in the first embodiment of the present invention.

FIGS. 3A and 3B are perspective views of using the die suction assistance device in a second embodiment of the present invention.

FIG. 4A is a three dimensional perspective view of a loading plate of the die suction assistance device in a third embodiment of the present invention.

FIG. 4B is an elevated perspective view of the loading plate of the die suction assistance device in the third embodiment of the present invention.

FIG. 4C is a cross-sectional view of the loading plate of the die suction assistance device in the third embodiment of the present invention.

FIGS. 4D and 4E are perspective views of using the die suction assistance device in the third embodiment of the present invention.

FIGS. 5A to 5C are flow charts of using a conventional die suction device.

FIGS. 6A and 6B are perspective views of defects of dies.

### DETAILED DESCRIPTION OF THE INVENTION

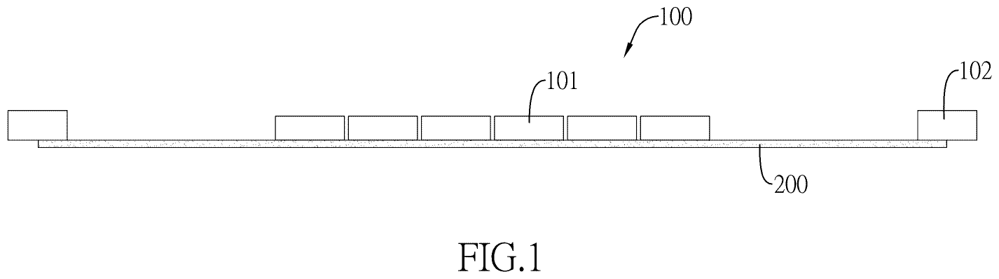

With reference to FIG. 1, the present invention provides a die suction assistance device. The die suction assistance device 1 is provided to a wafer 100 as shown in FIG. 1. The wafer 100 is diced into multiple dies 101, and a tape 200 is taped on a bottom side of the wafer 200. In an embodiment of the present invention, the wafer 100 has already completed expanding, and as such, spacing between any of the adjacent dies 101 provides enough space for a suction nozzle to pick up each of the dies 101.

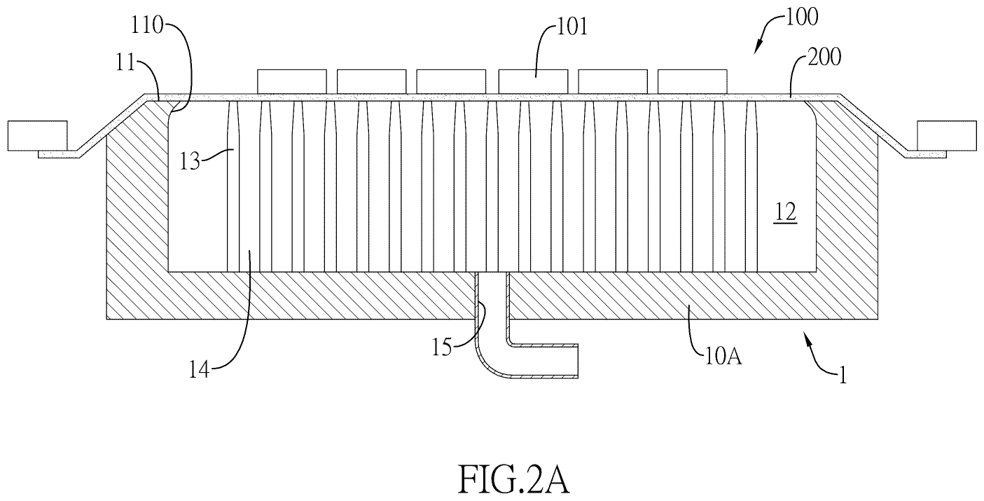

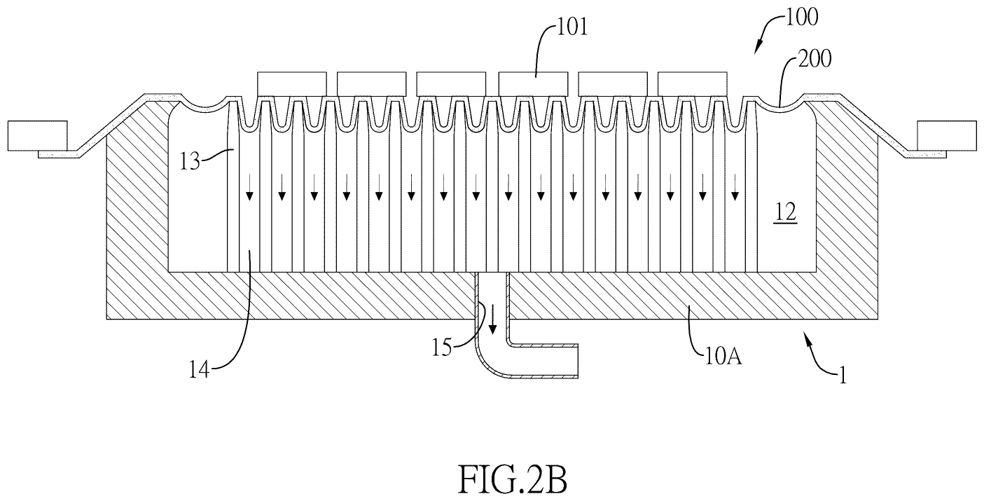

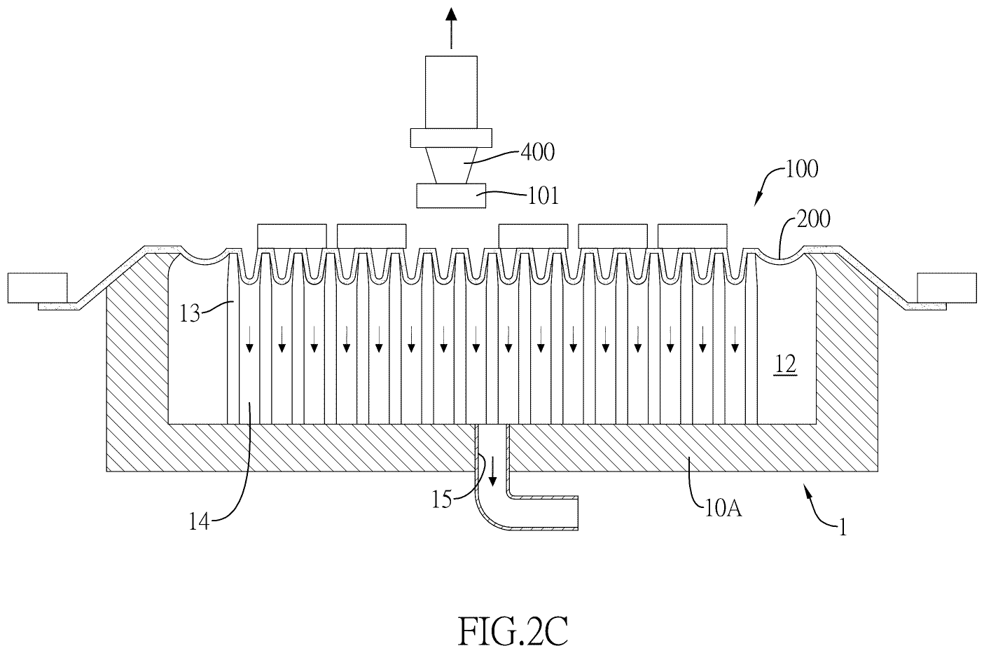

With reference to FIG. 2A, in a first embodiment of the present invention, a die suction assistance device 1 includes a platform 10A. The platform 10A has a top surface 11, and an opening 110 is formed on the top surface 11. An air cell 12 is formed extending inwards from the opening 110. On a bottom of the air cell 12, multiple support structures 13 are mounted vertically and aligned with each other. The support structures 13 also protrude from the opening 110, and the support structures 13 are uniformly distributed on the bottom of the air cell 12. As such, the support structures 13 are uniformly spaced, and multiple air ducts 14 are formed among the support structures 13. In this embodiment, each of the support structures 13 is shaped as a pin. A space between each of the adjacent support structures 13 is defaulted according to dimensions of each of the dies 101. This creates a correspondence between each of the dies 101 and a plurality of the support structures 13. Furthermore, at least one vacuum hole 15 is formed in the platform 10A, and the at least one vacuum hole 15 is in fluid communication with the air cell 12. The at least one vacuum hole 15 is connected to an external vacuum device (not shown in figures) for vacuuming air out of the air cell 12.

With reference to FIG. 2B, the top surface 11 of the platform 10A allows the wafer 100 to be mounted by fixing an edge of the wafer 100 on the top surface 11 of the platform 10A. The edge of the wafer 100 is fixed on the top surface 11 of the platform 10A by using conventional methods. Once the wafer 100 is fixed on the top surface 11 of the platform 10A, the tape 200 is able to air-tightly seal the opening 110 on the top surface 11, and a top of each of the support structures 13 is able to contact the tape 200. When the external vacuum device starts vacuuming, the air within the air cell 12 is vacuumed away along the air ducts 14 and the at least one vacuum hole 15 (as shown by the arrows). As a result, a vacuum environment with negative pressure is created within the air cell 12. This negative pressure pulls on the tape 200, causing parts of the tape 200 corresponding to positions of the air ducts 14 to slightly separate from a backside of the wafer 100 due to lack of support from the support structures 13. As such, the created vacuum environment decreases an adhesive force between each of the dies 101 and the tape 200.

With reference to FIG. 2C, once the tape 200 is separated from the backside of the wafer 100, each of the dies 101 is able to sustain a horizontal position without being tilted. A suction nozzle 400 provided to the present invention is able to suck each of the dies 101 upward, completely separating each of the dies 101 from the tape 200. By repeatedly re-positioning the suction nozzle 400, all of the dies 101 are able to be picked up from the tape 200 by the suction nozzle 400 correspondingly.

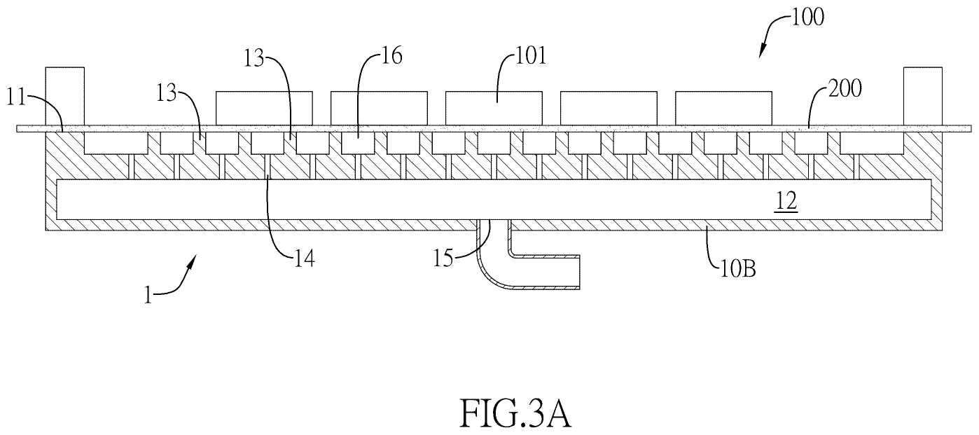

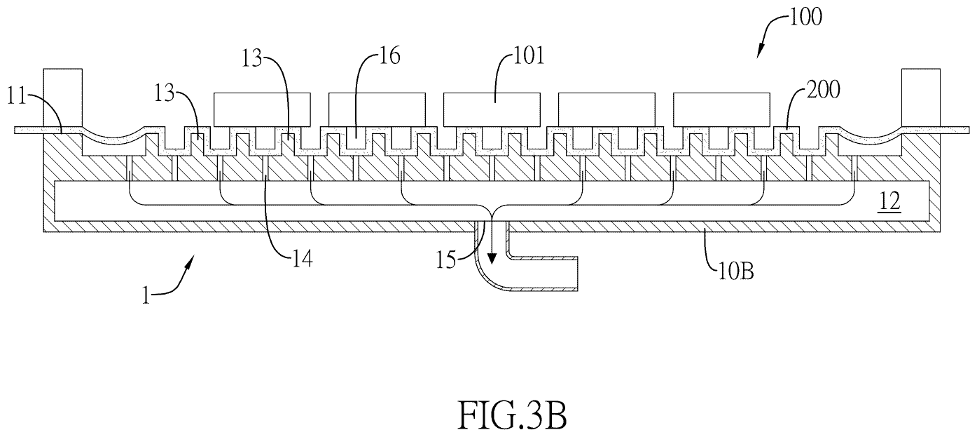

With reference to FIGS. 3A and 3B, in perspective views of using the die suction assistance device 1 in a second embodiment of the present invention, the die suction assistance device 1 similarly includes a platform 10B. An air cell 12 is similarly formed within the platform 10B, and at least one vacuum hole 15 is formed in the platform 10A, and the at least one vacuum hole 15 is in fluid communication with the air cell 12. Multiple air ducts 14 are formed on the top surface 11 of the platform 11B, and the air ducts 14 are also in fluid communication with the air cell 12. Multiple support structures 13 are also protruding upwards between each of the adjacent air ducts 14. The top of each of the support structures 13 contacts the tape 200 that is taped on the backside of the wafer 100. In this embodiment, multiple grooves 16 are formed crossing on the top surface 11 of the platform 11B. As a result, remaining parts of the top surface 11 of the platform 11B, apart from the grooves 16, naturally form the support structures 13. The air ducts 14 are formed as bottoms of the grooves 16, as the bottoms of the grooves 16 are in fluid communication with the air cell 12. Similarly, the space between each of the adjacent support structures 13 is defaulted according to the dimensions of each of the dies 101, creating a correspondence between each of the dies 101 and a plurality of the support structures 13.

With reference to FIG. 3A, the wafer 100 is fixed on the top surface 11 of the platform 11B. The wafer 100 is fixed on the top surface 11 also by using the conventional methods. Once the wafer 100 is fixed on the top surface 11 of the platform 10B, the tape 200 is able to air-tightly seal the opening 110 on the top surface 11, and the top of each of the support structures 13 is able to contact the tape 200.

With reference to FIG. 3B, when the external vacuum device starts vacuuming, the air within the air cell 12 is vacuumed away through the at least one vacuum hole 15 (as shown by the arrows). As a result, the vacuum environment with negative pressure is created within the air cell 12. Simultaneously, air below the tape 200 would also be vacuumed away through the air ducts 14, causing parts of the tape 200 corresponding to positions below the grooves 16 to slightly separate from a backside of the wafer 100. As such, the created vacuum environment decreases the adhesive force between each of the dies 101 and the tape 200, and allows each of the dies 101 to completely separate from the tape 200 when being picked up by the suction nozzle.

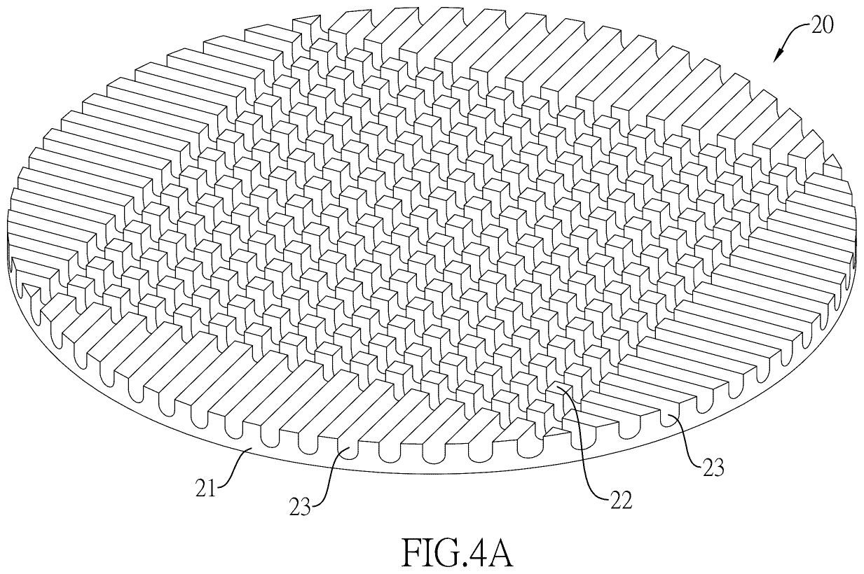

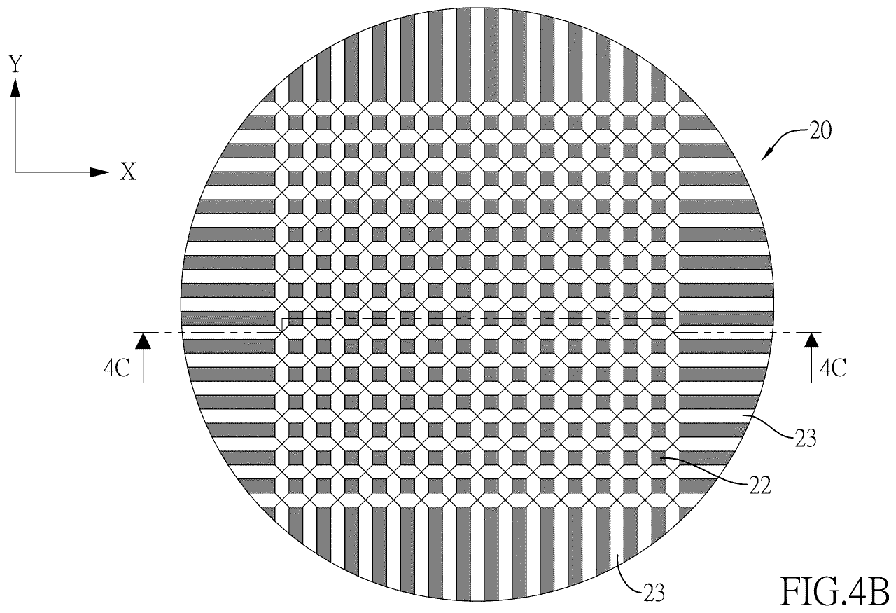

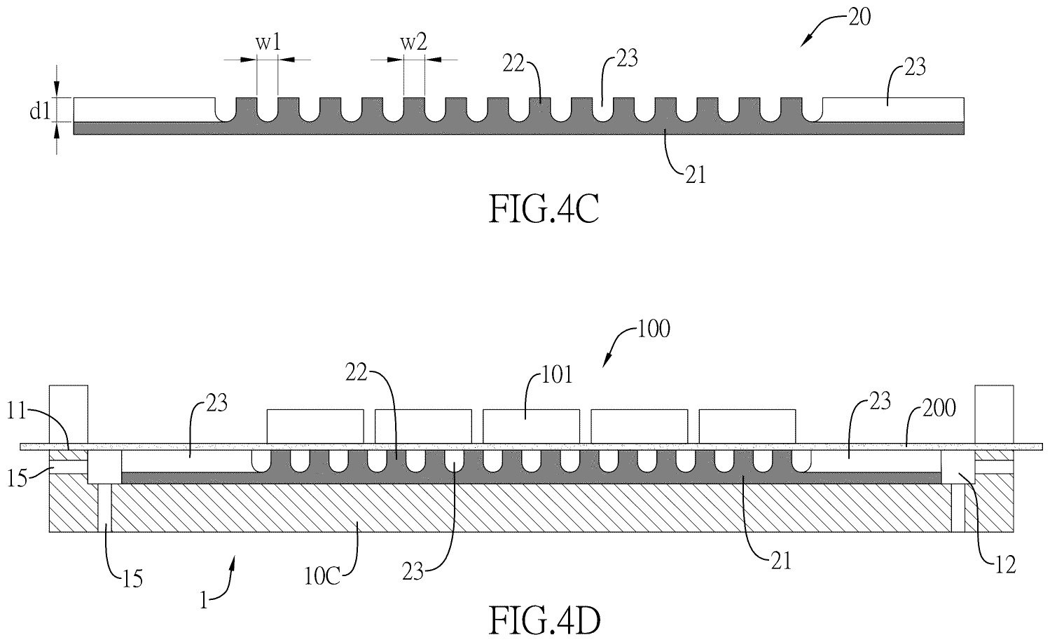

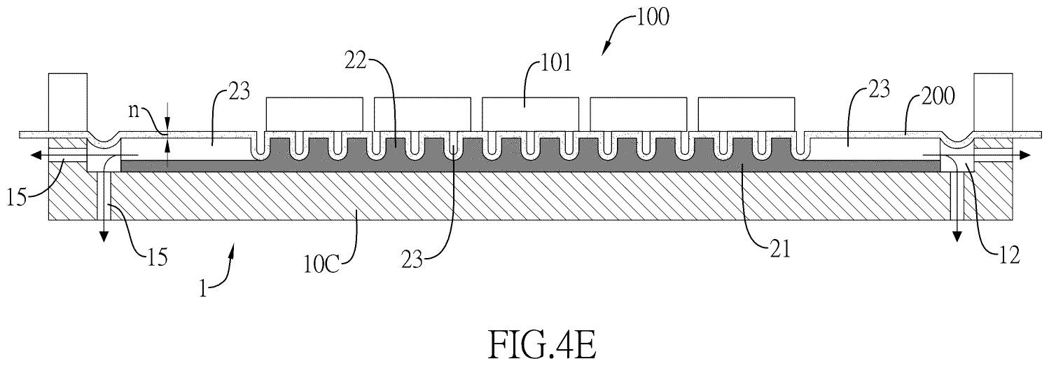

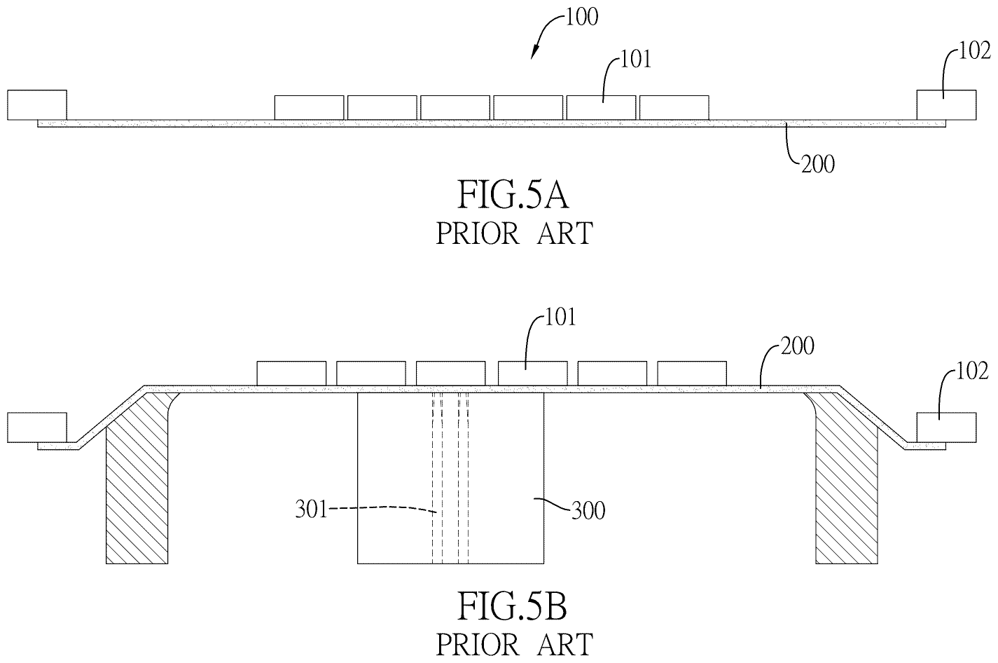

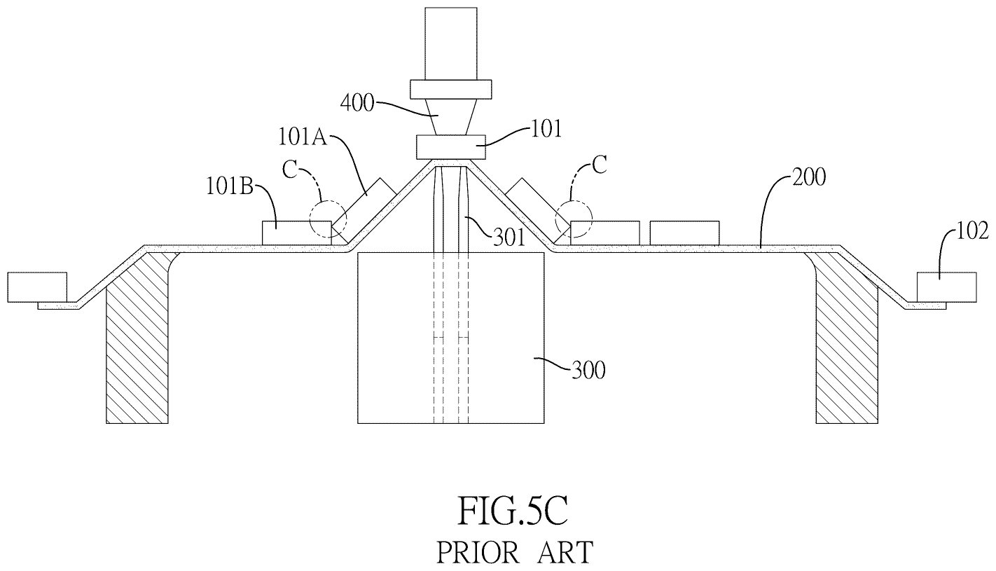

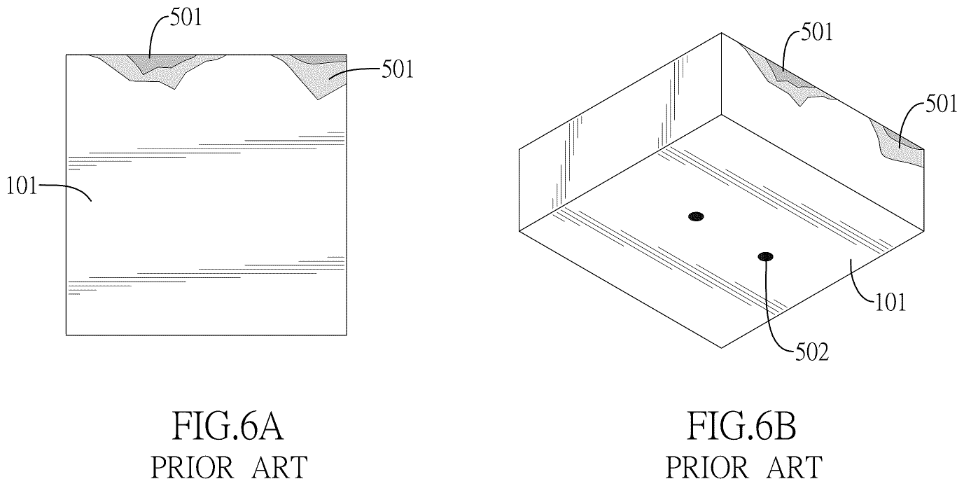

With reference to FIGS. 4A to 4E, in a third embodiment of the present invention, the die suction assistance device 1 includes a platform 10C and a loading plate 20. The loading plate 20 is made out of a board 21, and the board 21 is a metallic board. For example, the board 21 is a copper board. Multiple support structures 22 are formed on the board 21, and one of many ways to form the support structures 22 on the board 21 is by forming multiple grooves 23 crossing on a flat surface of the board 21. For example, the grooves 23 are formed crossing by using laser beams along an X axis and a Y axis to carve up the flat surface of the board 21, allowing each of the grooves 23 to extend to side surfaces of the board 21. As a result, remaining parts of the board 21 untouched by the laser beams naturally form the multiple independent support structures 22. In other words, each of the support structures 22 is formed by a part of the board 21 surrounded by the adjacent grooves 23. All top surfaces of the support structures 22 share same height, and therefore all the top surfaces of the support structures 22 share a flat surface. The support structures 22 can also be viewed as protruding from the top surface 11. The grooves 23 are formed between all of the adjacent support structures 22; in other words, each of the grooves 23 is formed between each pair of the adjacent support structures 22.

The aforementioned grooves 23 are free to be formed with any method that involves carving the board 21. For example, the grooves 23 may be carved by milling with mechanical blades. Furthermore, the crossing of the grooves 23 is free to form any angles. In other words, the grooves 23 may cross elsewise than just crossing perpendicularly in a form of a grid according to the X axis and the Y axis. The grooves 23 may be crossed tilted in different directions, and thus forming the support structures 22 with varying dimensions.

An air cell 12 is also formed within the platform 10C. The loading plate 20 is placed within the air cell 12. Furthermore, at least one vacuum hole 15 is formed in the platform 10C, and the at least one vacuum hole 15 is in fluid communication with the air cell 12. The at least one vacuum hole 15 is connected to an external vacuum device for vacuuming air out of the air cell 12.

With reference to FIG. 4D, the wafer 100 is mounted on the loading plate 20. An edge of the tape 200 is fixed on the top surface 11 of the platform 10C. For example, pinches may be used to pinch the edge of the tape 200 in order to fix the edge of the tape 200 on the top surface 11 of the platform 10C. As such, a bottom surface of the tape 200 is able to contact the support structures 22 mounted on the loading plate 20.

With reference to FIG. 4E, as the air is vacuumed out of the air cell 12 of the platform 10C by the external vacuum device, the air below the tape 200 would also be vacuumed away through the grooves 23 formed on the loading plate 20, and the air would be further expelled from each of the at least one vacuum hole 15 of the platform 10C as indicated by the arrows. After the air is vacuumed from the air cell 12, a vacuum environment with negative pressure is created within the air cell 12. This negative pressure pulls on the tape 200 located above the grooves 23 and causes the tape 200 to slightly separate from the backside of the wafer 100. As such, the vacuum environment decreases the adhesive force between each of the dies 101 and the tape 200, and thus allows each of the dies 101 to be more easily picked up from the tape 200 by the suction nozzle.

With reference to FIGS. 4C and 4E, a width w1 and a depth d1 of each of the grooves 23 are defaulted according to a thickness n of the tape 200. For example, a ratio between the width w1 of each of the grooves 23 and the thickness n of the tape 200 ranges as follows:
w1:n=2.5:1 to 3.5:1.

For instance, the ratio between the width w1 and the thickness n may also be: w1:n=3:1. Furthermore, a ratio between the depth d1 of each of the grooves 23 and the thickness n of the tape 200 ranges as follows:
d1:n=4:1 to 5:1.

As such, each of the grooves 23 would have enough space for contacting the tape 200 when the air cell 12 is vacuumed, which more easily allows the tape 200 to separate from the backside of the wafer 100 and stick to inner walls of each of the grooves 23.

A width w2 of each of the support structures 22 is defaulted according to the dimensions of each of the dies 101. For instance, when a length or a width of each of the dies 101 is dc, then a ratio between the width w2 of each of the support structures 22 and the length dc or the width dc of each of the dies 101 is:
w2:dc=1:3.

As such, an area encompassed by the dimensions of each of the dies 101 is able to encompass a plurality of the support structures 22, and when the air cell 12 is vacuumed, the tape 200 is able to partially separate from each of the dies 101 while each of the dies 101 is supported by a plurality, or at least two, of the support structures 22. As each of the dies 101 is supported by a plurality of the support structures 22, each of the dies 101 is able to maintain a horizontal position and avoids being tilted with balanced supports.

Overall, the die suction assistance device of the present invention allows for a vacuumed negative pressure environment to separate the tape 200 and each of the dies 101 preemptively. This allows each of the dies 101 to be more easily picked up subsequently. The die suction assistance device retains the following advantages:
1. The die suction assistance device 1 is able to prevent damage to the backside of each of the dies 101. Since the present invention avoids needing a pushing pin to quickly push each of the dies 101 upwards through the tape, each of the dies 101 avoids having pin wounds caused by the pushing pin on the backside of each of the dies 101 and avoids having residues of the tape 200 remaining on the backside of each of the dies 101.
2. The die suction assistance device is able to prevent chips or cracks on edges of each of the dies 101. Since each of the dies 101 is able to maintain the horizontal position when each of the dies 101 separates from the wafer 100, and that since each of the dies 101 is supported by a plurality of the support structures 22, when each of the dies is picked up by the suction nozzle, each of the adjacent dies 101 is able to stay balanced and avoids collisions with one another. As such, the present invention is able to lower probability of forming chips or cracks in the dies.
3. The present invention allows adjustments to distribution density of the support structures 22 in the die suction assistance device according to the dimensions of the dies 101. This allows each of the dies 101 to be supported by a plurality of the support structures 22. In some embodiments, the grooves may be carved from the board 21 with right density and widths, and as a result, forming the support structures 22 needed for the present invention. In some other embodiments, the support structures 22 are formed on the loading plate 20. The loading plate 20 may be customized to have various dimensions corresponding to different sizes of the wafer 100 and the dies 101. As such, when preparing to vacuum the air cell 12 for separating the tape 200 from the dies 101, the loading plate 20 may be easily swapped for changing the loading plate 20 corresponding to different designs of the wafer 100.

What is claimed is:

1. A die suction assistance device, comprising:
a platform, having an air cell; wherein at least one vacuum hole is formed in the platform; wherein the at least one vacuum hole is in fluid communication with the air cell; and
multiple support structures, mounted in the platform; wherein multiple air ducts are formed among the support structures, and the multiple air ducts are in fluid communication with the air cell;
wherein the die suction assistance device is provided to a wafer; the wafer is diced into multiple dies, and a tape is taped on a bottom side of the wafer;
wherein the at least one vacuum hole is connected to an external vacuum device for vacuuming air out of the air cell;
wherein the wafer is air-tightly mounted on the platform, and the support structures are configured to push against the tape;
wherein when the external vacuum device vacuums air out of the air cell, the tape and the dies are partially separated.

2. The die suction assistance device as claimed in claim 1, wherein:
the platform has a top surface, and an opening is formed on the top surface;
the air cell is formed extending inwards from the opening;
multiple support structures are mounted vertically and aligned with each other on a bottom of the air cell.

3. The die suction assistance device as claimed in claim 2, wherein each of the support structures is shaped as a pin.

4. The die suction assistance device as claimed in claim 1, wherein:
the platform has a top surface, and multiple support structures are formed protruding from the top surface; multiple grooves are formed between all of the adjacent support structures;
the air ducts are in fluid communication with the air cell located below the top surface.

5. The die suction assistance device as claimed in claim 1, wherein:
each of the dies is supported by at least two of the support structures.

6. A die suction assistance device, comprising:
a platform, having an air cell; wherein at least one vacuum hole is formed in the platform; wherein the at least one vacuum hole is in fluid communication with the air cell;
a loading plate, mounted within the air cell of the platform; wherein multiple support structures are formed on the loading plate, multiple air ducts are formed among the support structures, and the multiple air ducts are in fluid communication with the air cell;
wherein the die suction assistance device is provided to a wafer; the wafer is diced into multiple dies, and a tape is taped on a bottom side of the wafer;
wherein the at least one vacuum hole is connected to an external vacuum device for vacuuming air out of the air cell;
wherein the wafer is air-tightly mounted on the platform and is supported by the loading plate, and the support structures are configured to push against the tape;
wherein when the external vacuum device vacuums air out of the air cell, the tape and the dies are partially separated.

7. The die suction assistance device as claimed in claim 6, wherein:
the loading plate comprises a board, and multiple grooves are formed crossing in different directions on a surface of the board;
each of the grooves extends to side surfaces of the board;
each of the support structures is formed by a part of the board that is surrounded by the adjacent grooves.

8. The die suction assistance device as claimed in claim 7, wherein:
the board is a metallic board;
the grooves are formed crossing an X axis and a Y axis, and the grooves are carved by laser beams.

9. The die suction assistance device as claimed in claim 6, wherein:
each of the grooves has a width w1 and a depth d1, and the tape has a thickness n;
a ratio between the width w1 of each of the grooves and the thickness n of the tape ranges as follows:
w1:n=2.5:1 to 3.5:1; and
a ratio between the depth d1 of each of the grooves 23 and the thickness n of the tape 200 ranges as follows:
d1:n=4:1 to 5:1.

10. The die suction assistance device as claimed in claim 6, wherein:
each of the support structures has a width w2, and each of the dies has a length dc or a width dc;
a ratio between the width w2 of each of the support structures and the length dc or the width dc of each of the dies is:
w2:dc=1:3.
